(19) United States
(12) Patent Application Publication
(10) Pub. No.: US 2012/0200369 A1
(43) Pub. Date: Aug. 9, 2012

(54) DC BLOCKING DEVICE BY USING IMPEDANCE MATCHING

(75) Inventors: Jae-Won Jang, Incheon-si (KR); Dong-Wan Chun, Incheon-si (KR)

(73) Assignee: ACE TECHNOLOGIES CORPORATION, Incheon-si (KR)

(21) Appl. No.: 13/501,878

(22) PCT Filed: Oct. 15, 2010
(86) PCT No.: PCT/KR2010/007107

§ 371 Date: Apr. 13, 2012

(30) Foreign Application Priority Data
Oct. 15, 2009 (KR) 10-2009-0098244

(51) Int. Cl. H03H 7/38

(52) U.S. Cl. 333/33

(57) ABSTRACT

A DC blocking device using impedance matching is disclosed. The disclosed DC blocking device comprises: a first strip line configured to receive a signal and including a first line section and a first joining section joined to a part where a signal is received; and a second strip line separated from the first strip line at a designated distance and including a second line section and a second joining section for joining an output signal, where coupling occurs from the first strip line to the second strip line, the first strip line and the second strip line each have at least one bending section, and the first line section and the second line section have smaller line widths than the first joining section and the second joining section. The disclosed DC blocking device has the advantage of minimizing spatial constraints when it is installed in a mobile communication apparatus, and of achieving proper coupling even if the length of the part of the DC blocking device where coupling occurs is reduced.

### TECHNICAL FIELD

The present invention relates to a DC blocking device, more particularly to a DC blocking device used in a mobile communication system.

### BACKGROUND ART

DC blocking refers to eliminating DC components from signals and only passing frequency signals. Such DC blocking is required when DC signals are provided together with frequency signals for power supply in a device such as a mobile communication base station.

The study of DC blocking has been concentrated mainly on two-line micro-strip structure and two-line strip structure.

For the micro-strip structure, a DC blocking method using an inter-digital structure has been under study, for miniaturization of size and for broadening of the band. However, for the strip structure, there is a lack of study for miniaturization in a DC blocking device.

The existing strip-type DC block has been interpreted in terms of an approximate equivalent circuit on the basis of the even/odd concepts suggested by LaCombe and Cohen, and has used capacitive coupling.

FIG. 1 is a drawing illustrating the structure of a conventional strip-type DC blocking device.

Referring to FIG. 1, the conventional strip-type DC blocking device comprises a first strip line 100, a second strip line 102, and an insulator 104.

The first strip line 100 is composed of conductive material, and the first strip line 100 is electrically connected to a transmission line. For example, the first strip line may be electrically connected to an internal conductor within a connector.

A dielectric 104 is included between the first strip line 100 and the second strip line 102. The dielectric 104 electrically separates the first strip line 100 and the second strip line 102.

The second strip line 102 is composed of conductive material, and is included on top of the dielectric 104.

A capacitive coupling phenomenon occurs in the first strip line 100 and the second strip line 102 separated a designated distance by the dielectric 104. In other words, a coupling phenomenon occurs from the first strip line 100, where signals are input, to the second strip line 102.

As coupling occurs from the first strip line 100 to the second strip line 102, the DC signals included in the signals inputted into the first strip line are blocked and are not coupled with the second strip line. On the other hand, the frequency signals included in the signals input into the first strip line are coupled into the second strip line.

The second strip line is joined with a device for processing frequency signals such as a filter, an amplifier, etc., so that the coupled frequency signals are processed according to a pre-set method.

In such a conventional strip-type DC blocking device, the length of the part where coupling occurs (d in FIG. 1) should be greater than or equal to ¼ of the wavelength.

FIG. 2 is a graph illustrating reflection loss according to a change in length of the area where coupling occurs in a conventional strip-type DC blocking device such as that of FIG. 1.

Referring to FIG. 2, if the used frequency is 700 MHz, a length of about 160 mm should be obtained, and the larger the frequency gets, the shorter the length of the area where coupling occurs gets.

In this manner, since a length greater than or equal to ¼ of the wavelength corresponding to the used frequency needs to be obtained, there is difficulty in manufacturing the conventional strip-type DC blocking device in small sizes.

As a DC blocking device is inserted into an RF apparatus such as the input end of a filter, it needs to be implemented in a small size for the overall miniaturization of the RF apparatus.

### DISCLOSURE

### Technical Problem

To resolve the problem addressed above, an aspect of the invention is to provide a DC blocking device that may be Manufactured in a more miniaturized structure.

Another purpose of the present invention is to provide a DC blocking device with which spatial constraints may be minimized when mounted in an RF apparatus.

Yet another purpose of the present invention is to provide a structure wherein proper coupling may be achieved even if the length of the part in a DC blocking device where coupling occurs is reduced.

Other purposes of the present invention can be derived through the embodiments below by those skilled in the related art.

### Technical Solution

To achieve the objective above, an aspect of the invention provides a DC blocking device using impedance matching, comprising a first strip line configured to receive a signal and including a first line section and a first joining section joined to a part where a signal is received; and a second strip line separated from the first strip line at a designated distance and including a second line section and a second joining section for joining an output signal, where coupling occurs from the first strip line to the second strip line, the first strip line and the second strip line each have at least one bending section, and the first line section and the second line section have smaller line widths than the first joining section and the second joining section.

The DC blocking device may further comprise a dielectric included between the first strip line and the second strip line.

The first line section of the first strip line and the second line section of the second strip line may be identical in shape.

An inductive coupling phenomenon may occur due to mutual inductance between the bending section of the first strip line and the bending section of the second strip line.

Another aspect of the present invention provides a DC blocking device using impedance matching, comprising a first strip line configured to receive signals; and a second strip line placed at a designated distance from the first strip line, where coupling occurs from the first strip line to the second strip line, and the first strip line and the second strip line each include an inductive coupling structure for increasing an inductance component.

The inductive coupling structure may be such that the first strip line and the second strip line have at least one bending section.

### ADVANTAGEOUS EFFECTS

The present invention provides the advantages of minimizing spatial constraints when mounting a DC blocking device into a mobile communication apparatus, and of achieving proper coupling even when the length of the area where coupling occurs in the DC blocking device is reduced.

### DESCRIPTION OF DRAWINGS

FIG. 1 is a drawing illustrating the structure of a conventional strip-type DC blocking device.

FIG. 2 is a graph illustrating reflection loss according to a change in length of the area where coupling occurs in a conventional strip-type DC blocking device such as that of FIG 1.

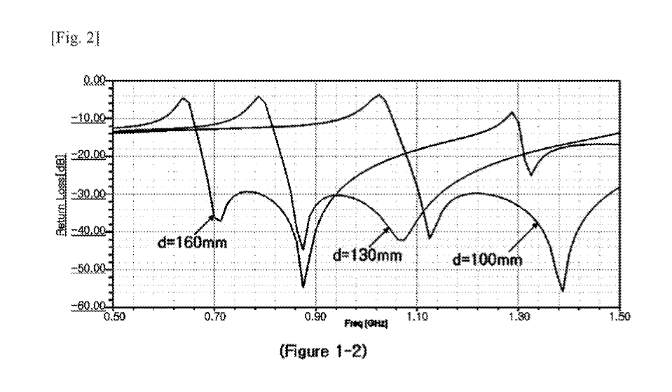

FIG. 3 is a drawing illustrating an example of an RF apparatus in which a DC blocking device using impedance matching according to an embodiment of the present invention is mounted.

FIG. 4 is a drawing illustrating a perspective view of a DC blocking device using impedance matching according to an embodiment of the present invention.

FIG. 5 is a drawing illustrating an exploded perspective view of a DC blocking device using impedance matching according to an embodiment of the present invention.

### MODE FOR INVENTION

The DC blocking device using impedance matching according to certain embodiments of the invention will be described below in more detail with reference to the accompanying drawings.

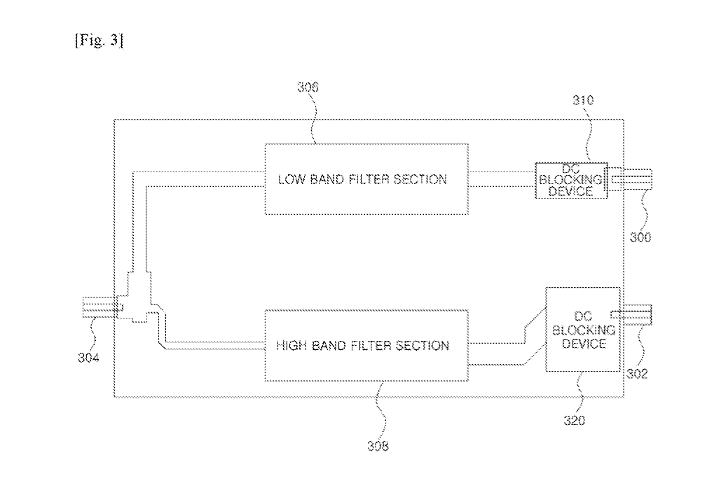

FIG. 3 is a drawing illustrating an example of RF apparatus in which a DC blocking device using impedance matching according to an embodiment of the present invention is mounted.

Referring to FIG. 3, an RF apparatus in which a DC blocking device using impedance matching according to an embodiment of the present invention is mounted may include a first input connector 300, a second input connector 302, an output connector 304, a low band filter section 306, a high band filter section 308, a first DC blocking device 310 and a second DC blocking device 320.

The RF apparatus illustrated in FIG. 3 is a diplexer for filtering signals of both bands. The DC blocking device according to the present invention can be applied not only to filtering devices such as a diplexer, but also to various RF processing devices, and it can also be implemented as an independent device without being built into an RF apparatus.

In FIG. 3, low band signals are inputted into the first input connector 300, and high band signals are inputted into the second input connector 302. Here, the high band and low band signals include DC components. As mentioned above, the DC components may be included for power supply, etc., or may be included in input signals due to unwanted noise.

The first input connector 300 is joined with the first DC blocking device 310, and the second input connector 302 is joined with the second DC blocking device 320. The first DC blocking device 310 blocks DC components from the low band signals inputted into the first input connector 300, and the second DC blocking device 320 blocks DC components from the high band signals inputted into the second input connector 302.

The first DC blocking device 310 only provides frequency signals out of the low band signals to the low band filter section 306, and the second DC blocking device 320 only provides frequency signals out oldie high band signals to the high band filter section 308.

The low band filter section 306 performs the function of only passing signals of a pre-designated low band, and the high band filter section 308 only passes signals of a pre-designated high band.

The low band filter section 306 and the high band filter section 308 illustrated in FIG. 3 have been implemented with the use of strip lines, and include multiple resonators. A detailed explanation of the strip line type of filter section will be foregone, as it is a widely known technology.

The frequency signals filtered at the low band filter section 306 and the high band filter section 308 are outputted through the output connector 304.

As was examined through FIG. 3, the DC blocking devices 310, 312 are generally installed at the tail end of an input connector so as to block DC before processing frequency signals. As described above, a conventional strip-type DC blocking device has to be of a length that is greater than or equal to ¼ of the wavelength of the frequency used, and since the size of an RF apparatus increases due to a DC blocking device when it is built into the RF apparatus as in the embodiment of FIG. 3, there is a need for it to be manufactured in a smaller size.

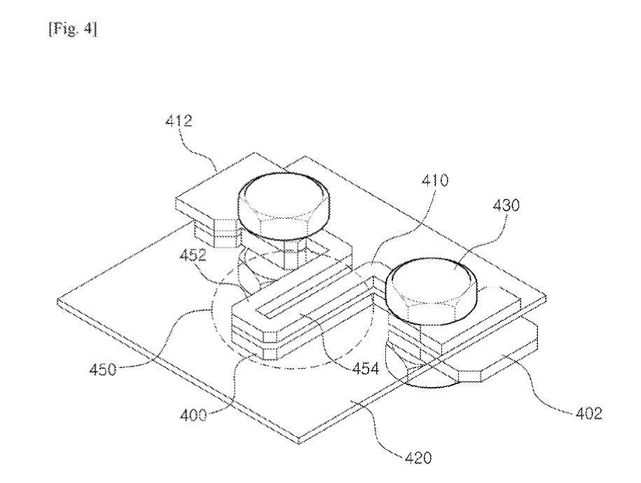

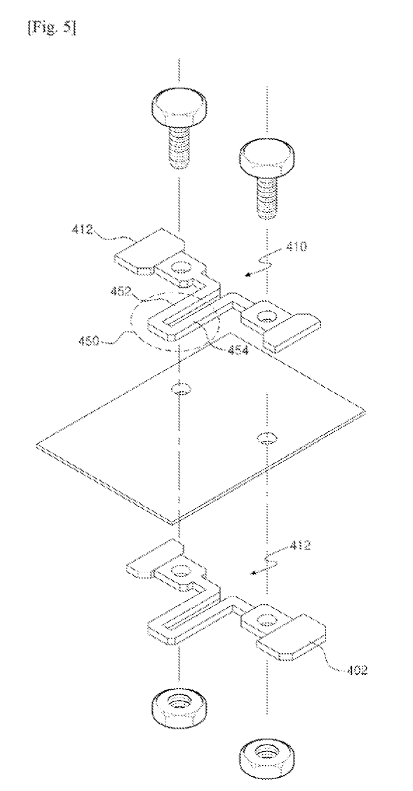

FIG. 4 is a drawing illustrating a perspective view of a DC blocking device using impedance matching according to an embodiment of the present invention, and FIG. 5 is a drawing illustrating an exploded perspective view of a DC blocking device using impedance matching according to an embodiment of the present invention.

Referring to FIGS. 4 and 5, a DC blocking device using impedance matching according to an embodiment of the present invention may include a first strip line 400, a second strip line 410, a dielectric 420, and a fastening bolt 430.

The first strip line 400 includes a first joining section 402 for joining with a connector. The first strip line is composed of conductive material and signals are input through the first joining section 402. Here, signals input into the first strip line 400 include frequency signals and DC signals.

A dielectric is included between the first strip line 400 and the second strip line 410. FIGS. 4 and 5 illustrate a dielectric in the form of a board, but it should be apparent to those skilled in the art that the shape of a dielectric is not limited to this. According to a particular embodiment of the present invention, a dielectric composed of Teflon may be included between the first strip line 400 and the second strip line 410.

The second strip line 410 includes a second joining section 412 for joining with an RF processing section (for example, a filter section or an amplification section). The second strip line 410 is also composed of conductive material. The second strip line 410 is separated from the first strip line 400 by a dielectric 420, by a distance corresponding to the thickness of the dielectric.

Referring to FIGS. 4 and 5, except for the joining sections 402, 412, the first strip line 400 and the second strip line 410, which come in contact with the dielectric 420, have identical shapes. As with a typical DC blocking device, coupling occurs between the first strip line 400 and the second strip line 410 separated by the dielectric 420. In other words, signals input into the first strip line 400 are coupled to the second strip line 410.

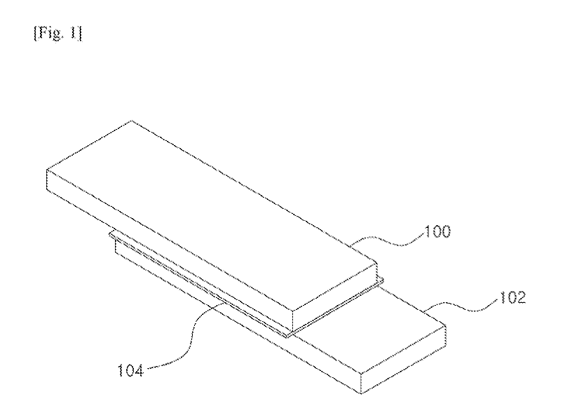

An ordinary strip line type DC blocking device as in FIG. 1 has a comparatively high capacitance component when verified by something like a smith chart. The present invention discloses a DC blocking device using impedance matching which can be implemented in a smaller size through a structure implementing proper impedance matching by offsetting such a high capacitive component with an inductance component.

As illustrated in FIGS. 4 and 5, the length of the parts on the first strip line 400 and the second strip line 410 that are coupled to the dielectric is thinner than the first joining section 402 and the second joining section 412. Also, the first strip line 400 and the second strip line 410 each include at least one bending section 450.

The bending sections 450 of the first strip line 400 and the second strip line 410 are structured to provide more effective impedance matching by increasing the inductance component. The first line section 452 and the second line section 454 contiguous to the bending section 450 have a line width smaller than the joining section 400, 412, thus structurally acting as inductors.

As an inductor is implemented structurally in this manner, an inductive coupling phenomenon occurs through mutual inductance in the bending sections of the first strip line and the second strip line, and such inductive coupling increases the inductance component to allow effective impedance matching.

In the embodiment illustrated in FIGS. 4 and 5, the first strip line 400, the second strip line 410 and the dielectric 420 are joined by means of fastening bolts 430. According to a particular embodiment of the present invention, use of fastening bolts 430 composed of Ultem is preferable. Of course, the first strip line 400, the second strip line 410, and the dielectric 420 may also be joined by a joining method other than using fastening bolts.

The DC blocking device illustrated in FIGS. 4 and 5 can be manufactured in a smaller size in the same frequency band as it improves impedance matching in the frequency band used, and unlike an ordinary strip-type DC blocking device which required ¼ length of the wavelength, can achieve effective DC blocking even with a shorter length.

1. A DC blocking device using impedance matching, comprising:
a first strip line configured to receive a signal and including a first line section and a first joining section joined to a part where a signal is received; and
a second strip line separated from the first strip line at a designated distance and including a second line section and a second joining section for joining an output signal,
wherein coupling occurs from the first strip line to the second strip line,
the first strip line and the second strip line each have at least one bending section, and the first line section and the second line section have smaller line widths than the first joining section and the second joining section.

2. The DC blocking device using impedance matching according to claim 1, further comprising:
a dielectric included between the first strip line and the second strip line.

3. The DC blocking device using impedance matching according to claim 2, wherein the first line section of the first strip line and the second line section of the second strip line are identical in shape.

4. The DC blocking device using impedance matching according to claim 1, wherein an inductive coupling phenomenon occurs due to mutual inductance between the bending section of the first strip line and the bending section of the second strip line.

5. A DC blocking device using impedance matching, comprising:
a first strip line configured to receive signals; and
a second strip line placed at a designated distance from the first strip line,
wherein coupling occurs from the first strip line to the second strip line, and
the first strip line and the second strip line each include an inductive coupling structure for increasing an inductance component.

6. The DC blocking device using impedance matching according to claim 5, wherein the inductive coupling structure is such that the first strip line and the second strip line have at least one bending section.

7. The DC blocking device using impedance matching according to claim 6, further comprising a dielectric included between the first strip line and the second strip line.
